(19) United States
(12) Patent Application Publication
(10) Pub. No.: US 2017/0221530 A1
(43) Pub. Date: Aug. 3, 2017

(54) COMPUTERIZED DEVICE FOR THE MARGINAL STATE ASSESSMENT OF POWER SYSTEMS

(71) Applicant: SYSTEM OPERATOR OF THE UNITED POWER SYSTEM, Moscow (RU)

(72) Inventors: Viktor Vasilyevich DAVYDOV, Ulan-Ude (RU); Petr Mikhailovich EROKHIN, Ekaterinburg (RU)

(21) Appl. No.: 15/218,360

(22) Filed: Jul. 25, 2016

(30) Foreign Application Priority Data
Jan. 29, 2016 (RU) 2016102906

(51) Int. Cl. G11C 5/14; H02J 13/00

(52) U.S. Cl. CPC G11C 5/14; H02J 13/00

(57) ABSTRACT

The required technical result aimed to raise a speed of device response is achieved in the device, which includes a group of operative memory blocks, a data acquisition block, memory block and marginal state assessment block, where operative memory blocks group outputs are connected with data acquisition block inputs, which output is connected, with marginal state assessment block input, which output is connected with the memory block input, and first and second outputs of marginal state assessment block are connected, respectively, with first and second inputs of the memory block.

### CROSS REFERENCE TO RELATED APPLICATIONS

The present application claims priority to Russian application RU2016102906 filed on Jan. 29, 2016.

### FIELD OF THE INVENTION

The invention is classified among the information, measurement and computer facilities and can be used for assessment of the steady state stability limits and for determining the power flow feasibility boundaries i.e. the marginal states (MS) of power systems on the basis of calculation of these states in the specified direction of power changes.

The assessment of marginal states plays a key role in the analysis, planning and control of power systems since this assessment finds such a stable steady state for which an arbitrarily small change in any of operating quantities in an unfavorable direction causes a voltage collapse or a loss of synchronism by units.

It is known the device for recording the parameters of voltage and current transient changes in networks under emergency conditions [RU 2376625, C1, G06F17/40, H02J3/00, 20.12.2009], including an analog sensor group, an digital sensor group, the first analog and the second digital multichannel commutators, an absolute value former, a zero control, a reference voltage source, a decoder, the first, the second and the third operative memory units, a constant memory unit, a microcontroller, a timer, the first the forth one-channel analog commutators, an analog-digital transducer, the first and the second analog comparators, a register, the first the fifth counters, the first the third triggers, a AND-NO element, the first the fifth AND elements, the first—the forth OR elements, the first—the sixteenth one-vibrators, a number comparator and a clock impulse generator.

The shortcoming of this device is its relatively limited functional opportunities since it allows only recording the parameters of voltage and current transient changes in networks under emergency conditions and does not make it possible to determine the marginal states of operation.

It is known also the device for remote monitoring of the current and voltage parameters in high voltage part of power systems including a control of transients in these systems [RU 2143165, C1, H02J13/00, 20.12.1999]. The device includes a high voltage measurement module which is connected to high voltage network and includes a network current passive transducer magnetically connected with high voltage network and/or a network voltage passive transducer electrically connected with high voltage network. The high voltage measurement module includes a secondary power supply unit and connected to this secondary power supply unit a low voltage feeding current transformer magnetically connected with high voltage network and/or a low voltage feeding voltage transformer electrically connected with high voltage network and switched into a circuit of a network voltage passive transducer and also having a filtering capacitor shunting a primary winding and connected in parallel with it a dampening resistor. The module includes also a measurement data signal active transducer connected with a network current passive transducer and/or a network voltage passive transducer and with a secondary power supply unit and having the radio frequency and/or optical outputs for transformed signals of measurement data. The network voltage passive transducer is made as a high voltage supporting capacitor connected in series with a low voltage circuit branch. All elements of the high voltage measurement module except the high voltage supporting capacitor are placed into an electric screen connected with a network conductor through a choking coil and a dampening resistor connected in parallel to it.

The shortcoming of this device is its relatively limited functional opportunities since it allows to carry out remote monitoring the parameters of voltages and currents in a high voltage part of networks and does not make it possible to determine the marginal states of operation.

Besides it is known the device [RU 2402067, C1, G06F17/40, Dec. 20, 2010], including an analog sensor group, a digital sensor group, the analog and digital commutators, the first the forth counters, a group of operative memory units, a constant memory unit, a microcontroller, a timer, a register, an analog-digital transducer, a clock impulse generator, D-triggers, the first—the forth one-vibrators.

The shortcoming of this device is its relatively limited functional opportunities since when recording the parameters of transients in power supply systems it does not make possible in particular to determine the maximum and emergency admissible power flows through the weak tie-line corridors in power systems. It limits the use of this device for assessment the marginal states of power systems.

The known system for stability margin monitoring in power system [RU 2013142113/08, A, G06F17/40, H02J3/00, publ. Mar. 27, 2015] is the technically nearest system to the proposed device. This system includes a group of operative memory units, a digital sensor group, a memory unit, a data acquisition and development block with the inputs connected to the outputs of operative memory units of the group, a power system state estimation block with the inputs connected with the output of data acquisition and development block and with the outputs of digital sensors of the group which are the sensors of telemeasurement system, and also connected in series the block of marginal states assessment with the input connected to the output of the power system state estimation, the block of weak tie-line corridors searching and the block of maximum and emergency admissible power flows calculation with the output connected to the input of memory unit.

The shortcoming of this device is its relatively low effectiveness since as it pointed out in instructions to the known device, a criterion of reaching the marginal states (MS) is a conversion of an iterative process of solving the nonlinear equations of steady state conditions. However a global convergence of the algorithms requires a lot of calculations, and a long duration of data development is a usual cost of reliable algorithms convergence. As a result of it a speed of device response becomes lower.

### SUMMARY OF THE INVENTION

The proposed invention is directed to solving a task of increasing a speed of device response when making an assessment the marginal states (MS) of power systems.

The required technical result includes raising a speed of device response when making an assessment the marginal states (MS) of power systems.

The defined task is solved and the required technical result is achieved by such a way that in the device including a group of operative memory blocks, a data acquisition and development block, an output memory block and also a marginal states assessment block, according to the invention, the outputs of operative memory blocks of the group are connected to the input of a data acquisition block, the output of this block is connected to the input of a marginal states assessment block and the output of it is connected to the input of an output memory block, a marginal states assessment block is realized in a form of connected in series a calculator of Lagrange multipliers vector the input of it is the input of a marginal states assessment block, a calculator of loading factor ultimate increment, a calculator of a sign of power flow matrix determinant, a calculator of increments and corrections and a calculator of convergence check that has the first output which is the first output of a marginal states assessment block and the second output connected to the additional input of a calculator of loading factor ultimate increment, and also a calculator of bifurcation with the input connected to the additional output of a calculator of a sign of power flow matrix determinant and the output which is the second output of a marginal states assessment block, besides the first and the second outputs of a marginal states assessment block are connected correspondingly with the first and the second inputs of an output memory block.

### BRIEF DESCRIPTION OF THE DRAWINGS

The following is presented on the figures:

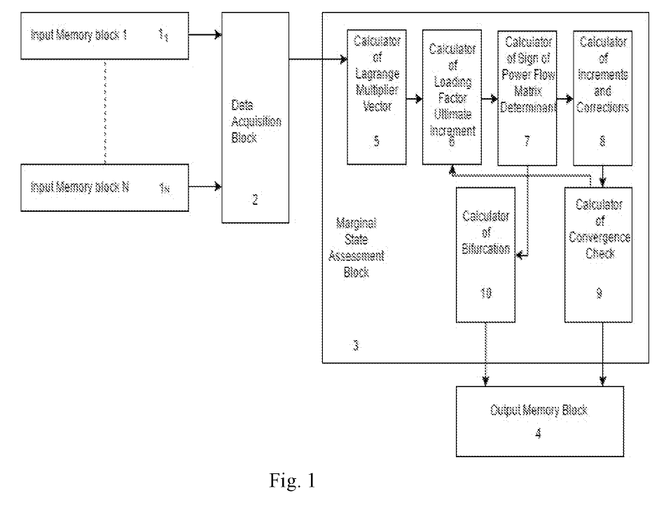

On FIG. 1—functional scheme of computerized device for the marginal state assessment of power systems;

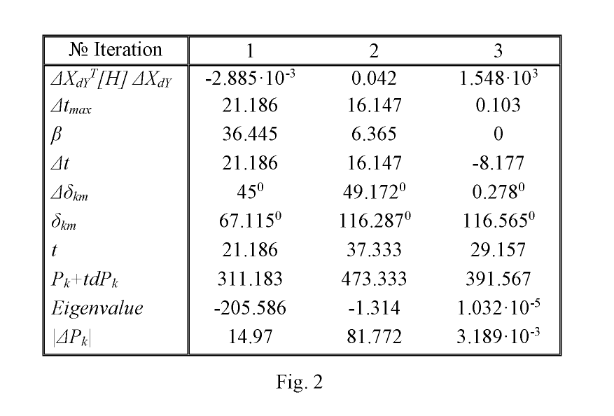

On FIG. 2—table of results of marginal states assessment for an example of two-node system.

### DETAILED DESCRIPTION OF THE INVENTION

The computerized device for the marginal state assessment of power systems (FIG. 1) includes a group of 1-1 . . . 1-n operative memory blocks, a data acquisition block 2, a marginal state assessment block 3 and an output memory block 4, in addition the outputs of 1-1 . . . 1-n operative memory blocks of the group are connected with the input of data acquisition block 2, the output of this block 2 is connected with the input of a marginal state assessment block 3, the first and the second outputs of this block 3 connected correspondingly with the first and the second inputs of an output memory block 4.

In the computerized device for the marginal state assessment of power systems a marginal state assessment block is made in a form of connected in series a calculator 5 of Lagrange multiplier vector with the input of this calculator being the input of a marginal state assessment block 3, a calculator 6 of loading factor ultimate increment, a calculator 7 of power flow matrix determinant sign, a calculator 8 of increments and corrections and a calculator 9 of convergence check, the first output of this calculator is the first output of a marginal state assessment block 3 and the second output of this calculator is connected with an additional input of a calculator 6 of loading factor ultimate increment, and also a calculator 10 of bifurcation the input of this calculator is connected with a additional output of a calculator 7 of power flow matrix determinant sign and the output of it is the second output of a marginal state assessment block 3, besides the first and the second outputs of a marginal state assessment block 3 are connected correspondingly with the first and the second inputs of an output memory block 4.

The proposed technical decision includes the elements characterized on the functional level and a described form of realization is supposed to use a programmable (adjustable) multifunctional facility, so further on description of its operation the information is presented that confirms an opportunity of this facility to perform the specific function required by the given technical decision particularly to solve the algorithms and mathematic expressions.

The computerized device for the marginal state assessment of power systems operates in the following way.

Preliminary let us perform a theoretical justification of the device operation algorithm.

The assessment of marginal states (MS) plays a key role in the analysis, planning and control of power systems. The MS is such a stable steady state for which an arbitrarily small change in any of operating quantities in an unfavorable direction causes a voltage collapse or a loss of synchronism by units.

One of the most commonly used approaches of the MS search consists of sequential load flow solutions with the given step along the specified trajectory until a divergence of load flow solution is obtained, which in turn is corrected by the binary search or by the damped Newton method. However, as soon as the network comes close to the condition of instability, a divergence in load flow solution may occur that is caused by the numerical problems of ill-conditioned Jacobian. That is why, in continuation methods the load flow parameterization, or the normalized iteration step change, are widespread. In this case the Jacobian of intermediate states and MS is not singular.

The MS model of power system can be presented as follows

min−t (1)

subject to

ΔF(X,Y+tdY)=0. (1a)

Here t is a scalar variable typically referred to as the loading factor.

System (1a) represents the active power balance equations at the PV and the PQ buses, and the reactive power balance equations at the PQ buses; the vector X represents the bus voltage angles (except the slack bus angle), and the PQ bus voltage magnitudes; the vector Y represents the active and reactive power at each load bus and the active power generated at each generator bus; the direction vector dY represents the user-defined changes in active and reactive power demand and the changes in active power generation.

The Lagrange function for (1)-(1a) can be presented as

L=−t+ΔF(X,Y+tdY)^{T}λ, a. (2)

where λ is a vector of auxiliary solution variables called Lagrange multipliers.

Differentiation of this function with respect to all variables yields

∇_{X}L=[J]^{T}λ=0; (3)

∇_{λ}L=ΔF(X,Y+tdY)=0; (3a)

∇ₜL=−1+dY^{T}λ=0. (3b)

Here ∇_{X}L=[∂L/∂X]^{T} is a gradient of the Lagrange function with respect to vector X, and [J]=[∂ΔF/∂X] is the load flow Jacobian.

Condition (3b) ensures that the vector λ will not be equal to zero at a solution point of (1)-(1a). That is why condition (3) determines the load flow Jacobian singularity, i.e., an MS.

In the MS the load flow Jacobian is singular. Contrary to it the matrix of linearized equations (3)-(3b)

$$[ \begin{matrix}H & {J}^{T} & 0 \\ J & 0 & dY \\ 0 & {dY}^{T} & 0\end{matrix} ] [ \begin{matrix}Δ X \\ Δλ \\ Δ t\end{matrix} ] = - [ \begin{matrix}{∇}_{X} L \\ {∇}_{λ} L \\ {∇}_{t} L\end{matrix} ] \qquad ( 4 )$$

is not singular at the solution point of (1)-(1a). Here [H]=└∂²ΔF^{T}λ/∂X²┘ is a matrix of second partial derivatives (Hessian).

Equations (3)-(3a) can be obtained directly from the implicit function theorem. In this case they have got the name of the point of the collapse (PoC) method, and in Russia they are called the MS equations. In existing PoC modifications the condition (3) in some cases is written for the right eigenvector of the Jacobian, which corresponds to the zero eigenvalue, while the Euclidean or the max norm of vector λ is used as the addend in (3b).

Researches have shown that the good initial guesses for the system variables, particularly the eigenvectors, are essential, otherwise the Newton approach for obtaining the solution to the PoC equations (3-3b) either yields undesirable results or does not converge. That is why, in spite of the fact that the PoC method surpasses the continuation methods in case of the successful solution, because of unreliability of the PoC method, many researchers prefer to use continuation methods, at least, for finding an initial MS.

Consider a 2-bus system with PV-bus k and slack bus m. In this case the problem (1)-(1a) will look as follows:

min−t

subject to

ΔPₖ=Pₖ+tdPₖ−Vₖ²|Yₖₘ|sin αₖₘ−VₖVₘ|Yₖₘ|sin(δₖₘ−αₖₘ)=0,

where t is the loading factor; δₖ, Vₖ are the voltage angle and magnitude at bus k; Pₖ is the active power at bus k; dPₖ is the given “direction” of active power change at bus k; |Yₖₘ| is the series admittance magnitude between buses k and m; αₖₘ=∠Yₖₘ+π/2 is a loss angle; δₖₘ=δₖ−δₘ.

The Lagrange function for this problem can be presented as

L=−t+[Pₖ+tdPₖ−Vₖ²|Yₖₘ|sin αₖₘ−VₖVₘ|Yₖₘ|sin(δₖₘ−αₖₘ)]λ.

The first-order optimality conditions are

∇_{δ}_{ₖ}L=−VₖVₘ|Yₖₘ|cos(δₖₘ−αₖₘ)λ=0; (5)

∇_{λ}L=ΔPₖ=Pₖ+tdPₖ−Vₖ²|Yₖₘ|sin αₖₘ−VₖVₘ|Yₖₘ|sin(δₖₘ−αₖₘ)=0; (5a)

∇ₜL=−1+dPₖλ=0. (5b)

Equation (5b) directly determines the Lagrange multiplier λ=1/dPₖ. Therefore if to use it as the initial guess of multiplier λ then only two linearized equations will be really used during iterations.

[VₖVₘ|Yₖₘ|sin(δₖₘ−αₖₘ)λ]Δₖ=VₖVₘ|Yₖₘ|cos(δₖₘ−αₖₘ)λ; (6)

[−VₖVₘ|Yₖₘ|cos(δₖₘ−αₖₘ)]Δδₖ+dPₖΔt=−ΔPₖ. (6a)

According to (6)

Δδₖ=ctg(δₖₘ−αₖₘ) (7)

Substitution of (7) in (6a) yields

Δt=−ctg(δₖₘ−αₖₘ)∇_{δ}_{ₖ}L−ΔPₖ/dPₖ. (8)

Depending on the initial state and the given direction dPₖ the multiplier in Δδₖ (6), which corresponds to the Hessian [H] in (4), can be positive or negative. The change of the state (7) will go only in one direction irrespective of the given direction dPₖ. In the case of δₖₘ>αₖₘ the voltage angle δₖₘ will increase, hence the MS will correspond to the maximum generation of active power at bus k. In the case of δₖₘ<αₖₘ the voltage angle δₖₘ will decrease, and the MS will correspond to the maximum load at bus k. The steady state with δₖₘ=αₖₘ is the “border-state” (BS) between the attraction regions to these MS. The determinant of matrix of equations (6)-(6a) is equal to VₖVₘ|Yₖₘ|sin(δₖₘ−αₖₘ). Therefore in the BS i.e., when δₖₘ=αₖₘ, the matrix of linearized equations (6)-(6a) is singular. In the BS neighbourhood this matrix is ill-conditioned. Therefore in the case of the “light” initial state, where δₖₘ≈αₖₘ, an increase in Δδₖ (7) and Δt (8) can be abnormal. As opposed to it in the MS the determinant has the highest absolute value. In the MS proximity the matrix of system (6)-(6a) is well-conditioned and the Newton method has a quadratic convergence.

In rectangular coordinates the MS will also depend on the initial steady state. An angle shift for more than one period is impossible, but the loading factor t and the bus voltage can essentially exceed required values. In the MS proximity the convergence speed turned out lower than in polar coordinates. It can be supposed that the usage of t² dP is a more successful alternative than tdP. However, it does not yield the desired result. If the initial Hessian [H] is not positive definite, the oscillatory iterative process emerges around the BS δₖₘ=αₖₘ. In the case of the positive definite matrix the convergence speed turned out noticeably worse than with tdP.

Thus, the presented analysis shows that for realization of the problem (1)-(1a) it is necessary to solve two problems. Firstly, the iterative process should generate a change of variables in the “correct” direction. Secondly, using the system of linear equations (4), it is necessary to apply mechanisms which take into account ill-conditioned matrix of this system. The theory of nonlinear programming has many procedures for these purposes. However, a common realization of these procedures has not yet allowed to create a computationally efficient algorithm of solution of the constrained minimization problem (1)-(1a).

There are two classical approaches for globalizing the locally convergent algorithm: line search procedures, or use of trust regions. The first approach requires the usage of a merit function. The selection of the merit function is ambiguous and strongly influences the speed of algorithm convergence. The second approach requires computationally costly procedures to support, e.g., positive definiteness of the Hessian, or in order that inertia of the matrix (4) satisfied the given conditions.

At the same time, the use of peculiarities of the system structure of linear equations (4) and the second-order optimality conditions for problem (1)-(1a) allows to create the simple, fast and reliable method of searching MS in a given direction of power change.

Let us consider a method of MS determination with a single slack bus.

Present the linearized equations system (4) in the following form

[H]ΔX+[J]^{T}Δλ=−∇_{X}L; (9)

[J]ΔX+dYΔt=−ΔF; (9a)

dY^{T}Δλ=−∇ₜL. (9b)

The system of nonlinear equations (3)-(3b) is the first-order optimality condition for problem (1)-(1a). According to the theory of nonlinear programming, a solution of the problems (1-1a) will be a point of the strict local minimum, if

Z^{T}[H]Z>0 (10)

for any vector Z which satisfies the equality constraint

[J]Z+dY·Zₜ=0, (10a)

where Zₜ is any scalar. Requirements (3)-(3b) and (10)-(10a) are known as the second-order sufficiency conditions.

Unlike an unconstrained minimization problem, conditions (10)-(10a) do not require the positive definite Hessian [H] at the solution point. It is enough to have the positive definite Hessian [H] along the direction Z.

Comparing (10a) with (9a) shows that (10a) is system (9a) with ΔF=0 i.e., when (9a) is homogeneous. Therefore, in order to take into account condition (10) during the problem solution (1)-(1a), represent vector ΔX as the sum of two vectors

ΔX=ΔX_{dY}Δt+ΔX_{ΔF}, (11)

where ΔX_{dY} and ΔX_{ΔF} are solution vectors of the following systems of linear equations:

[J]ΔX_{dY}=−dY; (12)

[J]ΔX_{ΔF}=−ΔF. (12a)

Substitution of (11) in (9) yields

Δλ=−[J^{T}]⁻¹(∇_{X}L+[H](ΔX_{dY}Δt+ΔX_{ΔF})). (13)

In turn, substitution of (13) in (9b) yields

Δt=−(α+ΔX_{dY}^{T}[H]ΔX_{ΔF})/(ΔX_{dY}^{T}[H]ΔX_{dY}), (14)

where a=∇ₜL+∇_{X}L^{T}ΔX_{dY}.

Comparing (10a) with (12) shows that ΔX_{dY}=Z/Zₜ. Hence ΔX_{dY}^{T}[H]ΔX_{dY}=Z^{T}[H]Z/Zₜ². Therefore, to provide a change of variables in the “right” direction, according to requirement (10) it is necessary that the denominator in (14) was positive. If it is not so, it is necessary to “correct” it. The simplest technique that at the same time has a theoretical substantiation is the increase of the diagonal elements of the Hessian [H] by a positive β>0 in (9). In this case (13) is changed and (14) is transformed to

$$Δ t = - \frac{a + Δ {X}_{dY}^{T} [ H ] Δ {X}_{Δ F} + βΔ {X}_{dY}^{T} Δ {X}_{Δ F}}{Δ {X}_{dY}^{T} [ H ] Δ {X}_{dY} + β {‖ Δ {X}_{dY} ‖}_{2}^{2}} , \qquad ( 14 a )$$

where ∥•∥₂ is the Euclidean norm.

The β value can be selected by the different ways, the basic requirement is

ΔX_{dY}^{T}[H]ΔX_{dY}+β∥ΔX_{dY}∥₂²>0. (15)

But this requirement is insufficient for reliable convergence of the method.

The analysis of the 2-bus system has shown that the matrix of linear equations (4), so (9)-(9b), is singular in the BS. For (14) it means that the denominator will be equal to zero. In the BS neighborhood this matrix is ill-conditioned and the denominator (14) will be much less than 1. As a consequence, a change of or (14) and also ΔX (11) and Δλ (13) will be excessive. According to (14a) β allows to reduce Δt, i.e., to improve the condition number of system (9)-(9b). For this purpose it is possible to take advantage of the trust regions ideology. If one way or another a permissible step size Δtₘₐₓ is specified, then fl can be obtained directly from (14a)

$$β = max \{ 0 , - \frac{a + Δ {X}_{dY}^{T} [ H ] Δ {X}_{Δ F} + Δ {X}_{dY}^{T} [ H ] Δ {X}_{dY} Δ {t}_{max}}{Δ {X}_{dY}^{T} Δ {X}_{Δ F} + {‖ Δ {X}_{dY} ‖}_{2}^{2} Δ {t}_{max}} \} . \qquad ( 16 )$$

Since the distance to the MS is not known beforehand and the dY size can be chosen arbitrarily, the best solution would be to reassign the Δtₘₐₓ value adaptively after the calculation of ΔX_{dY} from (12) in order to limit the maximum change of the voltage angles or other operating parameters at the iteration.

After determination of Δt from (14a), ΔX is obtained from (11), and Δλ—from the linear equations system solution

[J]^{T}Δλ=−(∇_{X}L+[H]ΔX+βΔX). (17)

The loading factor t is linearly included in (3a). After iteration it will change according to linearized expressions (9a) where nonlinear changes are not considered. For this reason, after each iteration the value of t can be corrected by

Δt_{c}=ΔF^{T}dY/∥dY∥₂². (18)

It reduces the Euclidean norm of the power mismatch vector and this vector becomes orthogonal to dY, that also improves the condition number.

Let's consider a method of MS determination with a distributed slack bus. In this case the load flow equations (1a) take the following form:

ΔF(X,Y+P^{S}α+tdY)=0, (19)

where P^{S} is the slack bus power; α represents the bus participation factors in the distributed slack bus with αₖ≧0 and Σαₖ=1.

When (19) is implemented for the problem (1)-(1a), (3b) will remain unchanged, (3a) will be replaced by (19), and (3) will be complemented by the following equation:

∇_{P}_{^{s}}L=λ^{T}α=0

Vectors ΔX_{dY} and ΔX_{ΔF} used in (11), (14a), and (16) are obtained by solving the following linear equations:

$$[ {J}_{LF}^{S} ] [ \begin{matrix}Δ {X}_{dY} \\ Δ {P}_{dY}^{S}\end{matrix} ] = - dY ; \\ [ {J}_{LF}^{S} ] [ \begin{matrix}Δ {X}_{Δ F} \\ Δ {P}_{Δ F}^{S}\end{matrix} ] = - Δ F ,$$

where [J_{LF}^{S}]=[J, α] is the load flow Jacobian with the distributed slack bus.

The Lagrange multiplier vector is obtained by solving the following linear equations set:

$${[ {J}_{LF}^{S} ]}^{T} Δλ = - [ \begin{matrix}{∇}_{X} L + [ H ] Δ X + βΔ X \\ 0\end{matrix} ] .$$

The slack bus power change is determined by the following expression:

ΔP^{S}=ΔP_{dY}^{S}Δt+ΔP_{ΔF}^{S}.

Like the loading factor, the slack bus power is linearly included in (19). For this reason after each iteration it can be corrected by −ΔF^{T}α/∥α∥₂², thereby compensating the projection of power mismatches onto vector α.

Let's consider the taking into account a limit-induced bifurcation.

The treatment of the generator reactive power constraints are performed just as in ordinary load flow solution. However if an MS corresponds to the limit-induced bifurcation (LIB) the iterative process can no converge because of LIB peculiarities: at least one of generator buses switches from PV type to PQ type and vice versa, repeatedly. Such situation occurs when a single generator in achieves its maximum reactive power limit Q⁺ₘ; dQₘ/dt>0, where Qₘ is the reactive output of the generator; the Jacobian is not singular, and if generator in switches from PV type to PQ⁺ type, the Jacobian determinant changes its sign (when load powers are positive in sign in load flow equations), and dVₘ/dt>0. Taking into account such peculiarities allows elaborating the following procedure of detection and determination of LIB.

The LIB monitoring is performed if the Jacobian determinant changes its sign. Using ΔX from (11), the PQ⁺-type generators for which the voltage magnitude at the iteration will exceed the specified value are detected. If such generators are not found, there is no LIB and the iteration of the MS determination procedure continues. On the other hand these generators are switched from PQ⁺ to PV type, and the following procedure of LIB determination is performed.
a. Step 1. Solve (12)-(12a) and calculate

$$t = {min}_{k ⋐ PV , \\ {∇}_{X} {Q}_{k}^{T} Δ {X}_{dY} > 0} ( - \frac{Δ {Q}_{k} + {∇}_{X} {Q}_{k}^{T} Δ {X}_{Δ F}}{{∇}_{X} {Q}_{k}^{T} Δ {X}_{dY}} ) ,$$

b. where ∇_{X}Qₖ is the gradient of reactive power balance equation for bus k with respect to X, ΔQₖ=Qₖ−Q⁺ₖ.
c. Obtain ΔX=ΔX_{ΔF}+tΔX_{dY} and update X.
d. Step 2 Check up the constraints for PQ-type generator buses. If constraints violations are found, then switch types of corresponding generators and return to step 1; else continue.
e. Step 3. Compute ΔQₘ=max|ΔQₖ|, k⊂PV. If max{∥ΔF∥_{∞}, |ΔQₘ|}>ε, then return to step 1; else continue.
f. Step 4. Switch the type of generator bus m from PV to PQ⁺ and solve (12). If ΔVₘ<0, then return to step 1; else STOP. The LIB is determined: the reactive power limit of generator bus m induces the bifurcation.

Thus if to take into account the procedure of detection and determination of LIB, the algorithm of the MS determination procedure can be presented as
a. Step 0. Solve the load flow for a base case and obtain an initial guess for λ by the inverse power method.
b. Step 1. Solve (12)-(12a). Obtain Δtₘₐₓ using ΔX_{dY}, then Δt and ΔX using (16), (14a), and (11).
c. Step 2. If the Jacobian determinant changes its sign, then run the LIB detection. If the LIB is detected, then run the LIB determination and STOP; else continue.
d. Step 3. Solve (17) to obtain Δλ. Update t, X, and λ, and next correct t by (18). Check for the reactive power limits and switch bus types if needed.
e. Step 4. Convergence check: if ∥ΔF∥_{∞}<ε and |σ|=∥∇_{X}L∥₂/∥λ∥₂<ε_{σ}, then STOP, else return to step 1.
f. The specified algorithm is realized in the proposed device by the following way.
g. In the computerized device for the marginal state assessment of power systems the current network parameters are entered into the operative memory blocks 1-1 . . . 1-1n of the group (FIG. 1) and are collected in a data acquisition block 2 as initial data necessary for performing calculations in a marginal state assessment block 3. The resulted marginal state assessments are put down into an output memory block 4.

The initial approximation of Lagrange multipliers vector λ is defined for example by the inverse power method in the calculator 5, and the input of this calculator is the input of a marginal state assessment block 3. It allows in a calculator 6 of loading factor ultimate increment by solving the system (12)-(12a) to calculate Δtₘₐₓ using ΔX_{dY} and then to calculate Δt [symbol] ΔX using (16), (14a) and (11). In calculator 7 of power flow matrix determinant sign a check is performed whether a sign of Jacobian matrix determinant has been changed or not. If Jacobian matrix determinant sign has been changed, in a calculator 10 of bifurcation a special procedure of LIB detecting and defining is performed and this fact corresponds to the end of the basic procedure of MS assessment and after that a signal from a calculator 10 output is entered into an output memory block 4. Otherwise a procedure of MS assessment is continued in a calculator 8 of increments and corrections, in this calculator an equation (17) is solved for obtaining Δλ, the values t, X, and λ are modified, and then t is corrected according to (18). Here also the limits on reactive power of generators are checked and if necessary a type of them is changed. After that a signal from the output of calculator 8 is entered to the input of a calculator 9 for a convergence check: ec [symbol] ∥ΔF∥_{∞}<ε and σ=∥∇_{X}L∥₂/∥λ∥₂<ε_{σ}, then a corrected value of t is entered into an output memory block 4 and it means the end of the basic procedure of MS assessment, otherwise a signal is transferred to a calculator 8 to continue calculations taking into account the modifications and corrections of t, X, and λ.

Let us consider an example of the proposed device application for two-bus power system. In Table (FIG. 2) the results of its application for MS assessment at the given direction of power change (increase of generation) at bus k are presented. The node data and results are presented for the following parameters of the system: Yₖₘ=−(20+j40)⁻¹Ω⁻¹, Vₖ=Vₘ=110 kV, Pₖ=100 MW, dPₖ=10 MW, αₖₘ=26.565⁰, δ⁰ₖₘ=22.115⁰, dΔPₖ/dδ⁰ₖₘ−269.748.

The system has two MS. One of them corresponds to the maximum generation at bus k, another—to the maximum load at this bus. The maximum generation turns out when δₖₘ−αₖₘ=π/2, thus the injected power will be equal to Pₖ^{max gen}=Vₖ²|Yₖₘ|sin αₖₘ+VₖVₘ|Yₖₘ|=391.567 MW. The maximum load turns out when δₖₘ−αₖₘ=−π/2, thus the consumed power will be equal to Pₖ^{max load}=Vₖ²|Yₖₘ|sin αₖₘ−VₖVₘ|Yₖₘ|=−149.567 MW at bus k. In the border-state (BS) i.e., when δₖₘ=αₖₘ, bus k injects Pₖ^{BS}=Vₖ²|Yₖₘ|sin αₖₘ=121 MW. Thus, the BS appears to be the equidistance state from these two MS.

Bus k injects 100 MW in the base case. Since Pₖ<Pₖ^{BS}, this state is close to the second MS. In the base case δₖₘ⁰=22.115⁰ and the line loss angle αₖₘ=26.565⁰. Since δₖₘ<αₖₘ, therefore the system solution (3)-(3b) should be the MS in the opposite direction of the given power change. I.e., model (1)-(1a) moves the system state to the closest MS in the power space. Moreover, the system matrix (4) is ill-conditioned in the initial state. The value of denominator (14) is equal to ΔX_{dY}^{T}[H]ΔX_{dY}=−2.885·10⁻³. If β is not used, then the system solution (4) will be Δt¹=−346.595 and Δδₖₘ¹=−736.1830⁰=−(4π+16.183⁰) at the first iteration. I.e., the voltage angle δₖₘ will be turned more than two times in the “wrong” direction. The proposed system overcomes these difficulties easily. FIG. 2 shows that ΔX_{dY}^{T}[H]ΔX_{dY} is negative at the first iteration. Therefore, according to (16) the matrix [H] is “corrected” by means of β. In order to improve the condition number, at each iteration the value of Δtₘₐₓ is determined so that the change of the voltage angle (ΔX_{dY}Δt) across the line does not exceed 45⁰. At the second iteration the value of ΔX_{dY}^{T}[H]ΔX_{dY} becomes positive, and β is used for improvement of the condition number. The MS calculation requires 3 iterations only. After the third iteration the power mismatch |ΔPₖ| is equal to 3.189·10⁻³ MW, and the load flow Jacobian eigenvalue achieves almost zero value, namely 1.032·10⁻⁵. Thus, the proposed system provides the fast, reliable and exact MS calculation. The accuracy is confirmed easily by the expression δₖₘ^{MS}=π/2+αₖₘ=90⁰+26.565⁰=116.565⁰ which should be carried out in the MS. After 3 iterations the voltage angle δₖₘ is equal exactly to this value.

Thus, due to the introduction of an additional arsenal of technical facilities the required technical result consisting in an increase of the device speed of response when performing the MS assessment in power systems, is achieved that is confirmed by experiment. The additional arsenal of technical facilities particularly consists in the following: the outputs of a group of operative memory blocks are connected with the input of a data acquisition block and the output of this block is connected with the input of a marginal state assessment block with its output connected to the input of an output memory block, a marginal state assessment block is performed in a form of connected in series a calculator of Lagrange multiplier vector with its input being the input of a marginal state assessment block, a calculator of loading factor ultimate increment, a calculator of a sign of power flow matrix determinant, a calculator of increments and corrections and a calculator of convergence check that has the first output which is the first output of a marginal states assessment block and the second output connected to the additional input of a calculator of loading factor ultimate increment, and also a calculator of bifurcation with the input connected to the additional output of a calculator of a sign of power flow matrix determinant and the output which is the second output of a marginal state assessment block, besides the first and the second outputs of a marginal state assessment block are connected correspondingly with the first and the second inputs of an output memory block.

What we claim is:

1. A computerized device for a marginal state assessment of power systems, comprising:
a group of operative memory blocks, a data acquisition block, an output memory block, and a marginal state assessment block,
wherein an output of the operative memory blocks of the group are connected with an input of the data acquisition block,
wherein an output of the data acquisition block is connected with an input of the marginal state assessment block,
wherein a first output of the marginal state assessment block is connected with an input of the output memory block,
wherein the marginal state assessment block comprises a series of calculators, said series of calculators comprising a calculator of a Lagrange multiplier vector, a calculator of loading factor ultimate increment, a calculator of sign of power flow matrix determinant, a calculator of increments and corrections, and a calculator of convergence check,
wherein an input of the calculator of a Lagrange multiplier vector is the input of the marginal state assessment block,
wherein an output of the calculator of a Lagrange multiplier vector is an input of the calculator of loading factor ultimate increment, an output of the calculator of loading factor ultimate increment is an input of the calculator of sign of power flow matrix determinant, an output of the calculator of sign of power flow matrix determinant is an input of the calculator of increments and corrections, and an output of the calculator of increments and corrections is an input of the calculator of convergence check,
wherein a first output of the calculator of convergence check is the first output of the marginal state assessment block and a second output of the calculator of convergence check is connected with an additional input of the calculator of a loading factor ultimate increment and further connected to the calculator of a sign of power flow matrix determinant, further connected to a calculator of bifurcation,
wherein an output of the calculator of bifurcation is a second output of the marginal state assessment block,
wherein the first and the second outputs of the marginal state assessment block are connected correspondingly with the first and the second inputs of the output memory block.

2. A method for performing a marginal state assessment of a power system, comprising:
receiving one or more outputs from a group of operative memory blocks,
sending the one or more outputs to an input of a data acquisition block,
sending an output of the data acquisition block to an input of a marginal state assessment block, within said marginal assessment block:
first calculating a Lagrange multiplier vector using the output of the data acquisition block,
second calculating a loading factor ultimate increment using the output of the Lagrange multiplier vector,
third calculating a sign of power flow matrix determinant using the loading factor ultimate increment,
fourth calculating increments and corrections,
fifth calculating a convergence check, thus forming a first output of the marginal state assessment block, said first output of the marginal state assessment block being a first input of an output memory block,
additionally sending said first output of the marginal state assessment block to calculate a second loading factor ultimate increment, said loading factor ultimate increment being used to calculate a second sign of power flow matrix determinant, said second sign of power flow matrix determinant being used to calculate a bifurcation, wherein the bifurcation is a second output of the marginal state assessment block, said second output of the marginal state assessment block being a second input of the output memory block,
and making a final determination within the output memory block, the final determination comprising an indicator of at least one marginal state of the power system.

3. The device of claim 1, wherein a constraint violation determined by the marginal state assessment block causes a switch in a corresponding generator.

4. The device of claim 1, wherein an output of the marginal state assessment block causes a switch in a corresponding generator bus from PV to PQ⁺.
